(19) United States
(12) Patent Application Publication
(10) Pub. No.: US 2014/0361800 A1
(43) Pub. Date: Dec. 11, 2014

(54) METHOD AND APPARATUS FOR HIGH VOLUME SYSTEM LEVEL TESTING OF LOGIC DEVICES WITH POP MEMORY

(71) Applicant: Qualcomm Incorporated, San Diego, CA (US)

(72) Inventors: Karthik Ranganathan Vishwanathan, San Diego, CA (US); Rae-Ann S. LoCicero, La Jolla, CA (US); Michael A. Monroe, Poway, CA (US); Anthony T. Newman, San Diego, CA (US); Nathan M. Luke, San Diego, CA (US); Fadi G. Kanj, Escondido, CA (US); Sajjad I. Pagarkar, San Diego, CA (US); Jatin N. Patel, San Diego, CA (US)

(73) Assignee: Qualcomm Incorporated, San Diego, CA (US)

(21) Appl. No.: 14/154,064

(22) Filed: Jan. 13, 2014

Related U.S. Application Data
(60) Provisional application No. 61/831,606, filed on Jun. 5, 2013.

(51) Int. Cl. G01R 31/28

(52) U.S. Cl. CPC G01R 31/2893
USPC 324/750.25

(57) ABSTRACT

A method and apparatus for high volume testing of logic devices with package-on-package (POP) memory. The apparatus includes a handler arm, compound nest attached to the handler arm, swing arm and a socketed assembly that facilitates alignment. In the method, a logic device is first installed in a compound nest. The compound nest is them attached to a handler arm. The compound nest is then aligned with a socketed assembly using a swing arm. Fine tuning of the alignment may be performed using guide pins and shoulder screws.

### CROSS-REFERENCE TO RELATED APPLICATION(S)

This application claims the benefit of U.S. Provisional Application Serial No. 61/831,606, entitled “METHODOLOGY TO TEST HIGH VOLUME FOR LOGIC DEVICES WITH POP MEMORY ON AUTOMATED HANDLER USING A SWING ARM, COMPOUND NEST AND MODIFIED SOCKETED CDP” and filed on Jun. 5, 2013, which is expressly incorporated by reference herein in its entirety.

### BACKGROUND

1. Field

The present disclosure relates generally to wireless communication manufacturing testing as well as to electronic device testing in general. More specifically, the disclosure relates to a method and apparatus for high volume testing of logic devices with package-on-package (POP) memory.

2. Background

As use of mobile devices grows, so does the need to manufacture and test new devices in an efficient manner. Testing is crucial for the logic devices incorporated into most mobile devices. Logic devices for mobile devices are often comprised of a mobile station modem (MSM) or application processor (APQ) and adjacent memory. In the past, the MSM or APQ or other logic device was mounted on a circuit board using ball grid array (BGA) pads on the bottom of the device and the memory used by the device located adjacent to the logic device. The memory was connected to the device through traces on the circuit board. The trace lengths needed to connect the logic device and the memory not only occupy needed circuit board area, but hinder or prevent high speed operation of the system. Also mobile devices have become smaller, while at the same time incorporating more features and capabilities, the need for space on the circuit boards has become acute. This is an additional reason as to why POP devices are now mounted directly on top of the logic device.

The above reasons (device speed and area) led to the development of POP devices which have BGA balls on the top surface of the logic chip or device. These BGA balls allow mounting of a memory device directly on top of the logic or MSM device served. This development has been driven in part by the need to conserve scarce circuit board area and also by increasing device speeds. Device speeds have increased from 166 Mhz (DDR-1) to the current 800-933 Mhz (DDR 3) and will increase to 1.6 GHz in the very near future. This increase in speed has further accelerated the use of POP devices.

The POP configuration has complicated testing of the devices and the memory chips. Automated (handler based) systems level testing requires that a POP memory device be placed in an automated fashion in a precise alignment directly on top of the MSM device in a socket on the test circuit board. Not only must the alignment be precise, but the amount of force exerted on the MSM device and the POP memory during placement must be sufficient to place the device and light enough not to damage the device or memory. In addition, the entire process must be sufficiently precise to allow automatic testing of a large number of logic devices without adjustment.

Testing only the POP memory of the stacked logic or MSM device does not resolve the problems stated above. An additional step of removing the POP memory from the stack is needed prior to sending the device to the customer is required. This complicates and lengthens the test and delivery sequence. Moreover, this approach is not scalable for high volume production due to the added costs and complexity. A further drawback is that any issues found cannot be isolated to the memory or to the logic device, as the reporting is only for the stacked composite structure.

There is a need in the art for methods and apparatus for automated testing of POP products that have speeds beyond 500 MHz. More particularly, there is a need in the art for a method and apparatus for testing logic devices without a POP memory present and then automatically placing the POP memory on top of a socketed MSM or base logic chip in a manner that allows automatic replacement of the MSM device.

### SUMMARY

Embodiments disclosed herein provide a method for high volume testing of logic devices with package-on-package (POP) memory. The apparatus includes compound nest attached to the regular handler arm or test chuck, a second swinging handler arm, and a socketed assembly that facilitates alignment.

A further embodiment provides a method for testing logic devices having an attached memory. The logic device is first installed in a compound nest. The compound nest is them attached to a handler arm. The compound nest is then aligned with a socketed assembly using a swing arm. Fine tuning of the alignment may be performed using guide pins and shoulder screws.

A still further embodiment provides an apparatus for testing logic devices having an attached memory. The apparatus includes: means for installing a logic device in a compound nest, means for attaching the compound nest to a handler arm; means for aligning the compound nest with the socketed assembly; and means for testing the logic device and attached memory.

### BRIEF DESCRIPTION OF THE DRAWINGS

FIG. 1 depicts a compound nest apparatus according to an embodiment.

FIG. 2 illustrates a handler swing arm and the alignment mechanisms in accordance with certain embodiments of the disclosure.

FIG. 3 shows the modified base plate and socket used in conjunction with the compound nest and handler swing arm, according to an embodiment of the disclosure.

FIG. 4 shows a flow chart of a method for high volume testing of logic devices with POP memory, according to an embodiment.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer / tablet / phone related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

As used herein, the term “determining” encompasses a wide variety of actions and therefore, “determining” can include calculating, computing, processing, deriving, investigating, looking up (e.g., looking up in a table, a database or another data structure), ascertaining and the like. Also, “determining” can include resolving, selecting choosing, establishing, and the like.

The phrase “based on” does not mean “based only on,” unless expressly specified otherwise. In other words, the phrase “based on” describes both “based only on” and “based at least on.”

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The various illustrative logical blocks, modules, and circuits described in connection with the present disclosure may be implemented or performed with a general purpose processor, a digital signal processor (DSP), an application specific integrated circuit (ASIC), a field programmable gate array (FPGA), or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core or any other such configuration.

The steps of a method or algorithm described in connection with the present disclosure may be embodied directly in hardware, in a software module executed by a processor or in a combination of the two. A software module may reside in any form of storage medium that is known in the art. Some examples of storage media that may be used include RAM memory, flash memory, ROM memory, EPROM memory, EEPROM memory, registers, a hard disk, a removable disk, a CD-ROM, and so forth. A software module may comprise a single instruction, or many instructions, and may be distributed over several different code segments, among different programs and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in software, the functions may be stored as one or more instructions on a computer-readable medium. A computer-readable medium may be any available medium that can be accessed by a computer. By way of example, and not limitation, a computer-readable medium may comprise RAM, ROM, EEPROM, CD-ROM or other optical disk storage, magnetic disk storage, or other magnetic storage devices, or any other medium that can be used to carry or store desired program code in the form of instructions or data structures and that can be accessed by a computer. Disk and disc, as used herein, includes compact disk (CD), laser disk, optical disc, digital versatile disk (DVD), floppy disk, and Blu-ray ® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

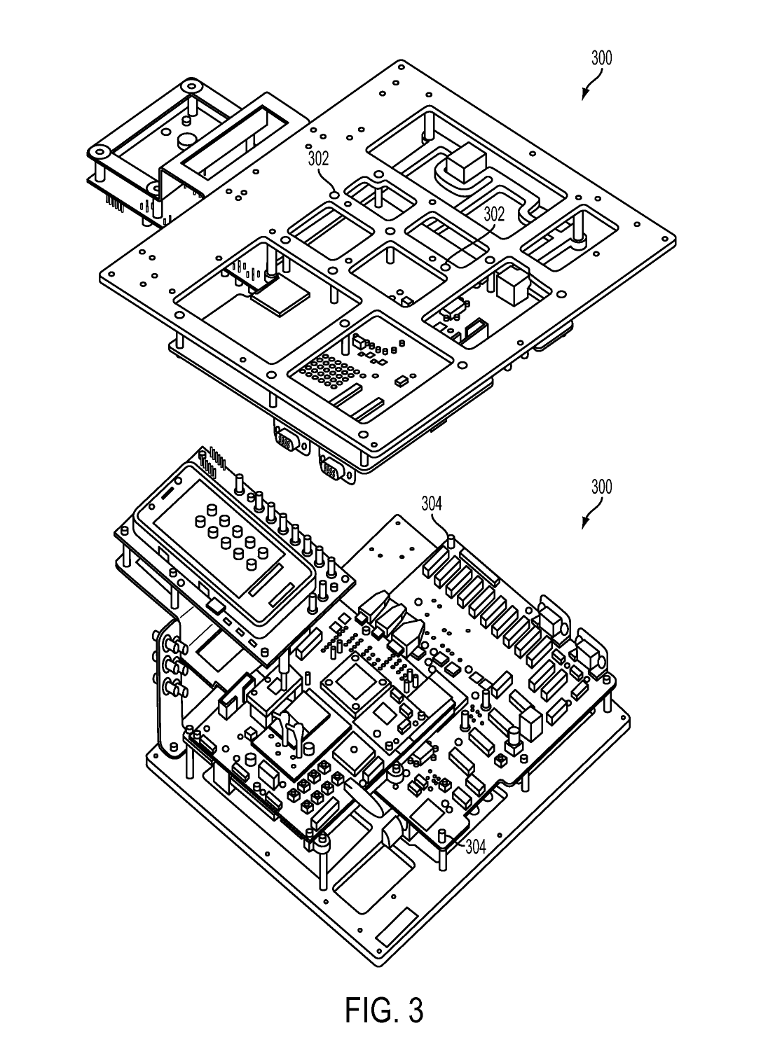

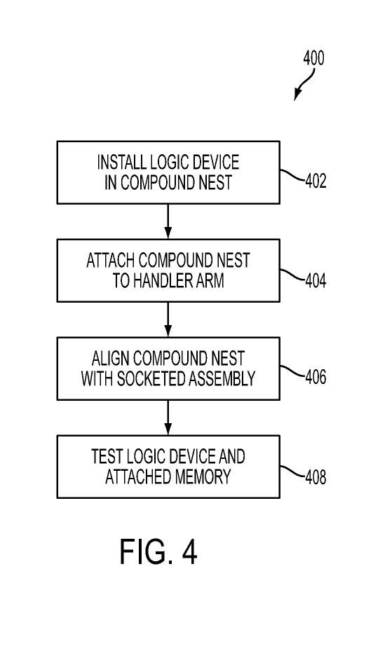

Further, it should be appreciated that modules and/or other appropriate means for performing the methods and techniques described herein, such as those illustrated by FIGS. 3 and 4, can be downloaded and/or otherwise obtained by a mobile device and/or base station as applicable. For example, such a device can be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a mobile device and/or base station can obtain the various methods upon coupling or providing the storage means to the device. Moreover, any other suitable technique for providing the methods and techniques described herein to a device can be utilized.

A key problem for testing logic chips in high volume production facilities is placing a POP memory device on top of a logic device with excellent alignment. The problem is compounded in that the placement must be repeated for each MSM tested. Even small and seemingly innocuous steps may significantly increase testing time when multiplied by the thousands of MSM and other logic devices needed.

Several key alignment features need to be addressed simultaneously: alignment of the MSM or logic device within the testing socket; POP memory placed on top of the MSM device, referred to herein as a “nest” when the devices are stacked; and alignment of the swing arm relative to the nest and to the device installed in a socket, or “socketed” device attached to a handler base plate.

The embodiments disclosed herein address the above problems by providing three elements: a swing arm that drops the logic device into a test socket, then applies a memory device to the pads or solder balls on top of the logic device; a compound nest with memory attached to a handler arm; and a base board with traces for testing.

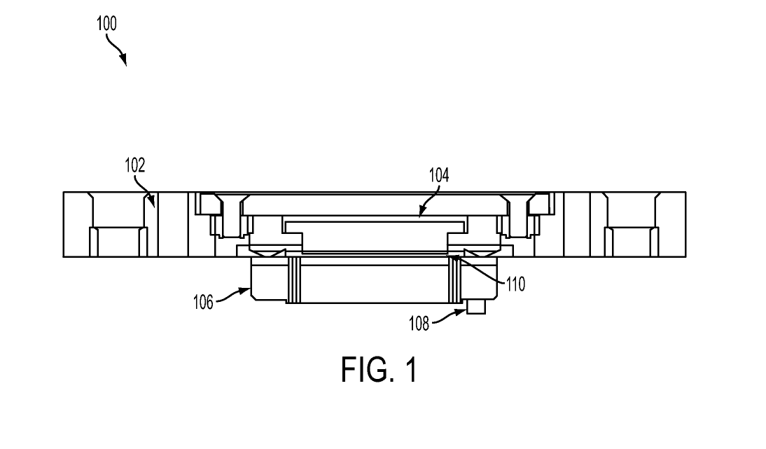

FIG. 1 illustrates an assembly 100 with the compound nest attached to the handler arm. The compound nest 100 encompasses the high speed memory chip in various thicknesses. A test head interface plate 102 ensures correct alignment when used in conjunction with the additional features described herein. A spring loaded platen 104 is used to help keep the memory in place and also supports different memory thicknesses. The pogo nest 106 is also shown in FIG. 1. The compound nest 100 incorporates a spring loading feature to allow testing different thicknesses of memory devices and also facilitates optimum pressure application to the memory. Also included in the compound nest are locating and locking alignment features to ensure that the compound nest is accurately positioned to work with the handler arm and socket assembly. These locking features placed on the compound nest allow provide fine alignment to the socket of the logic device or MSM device.

Locating pins 108 are one of two fine alignment features that operate to provide fine alignment of the pogo nest 106. These two alignment pins also align with the test head, which is not depicted in FIG. 1. The memory device is shown in FIG. 1 seated in the pogo nest as item 110.

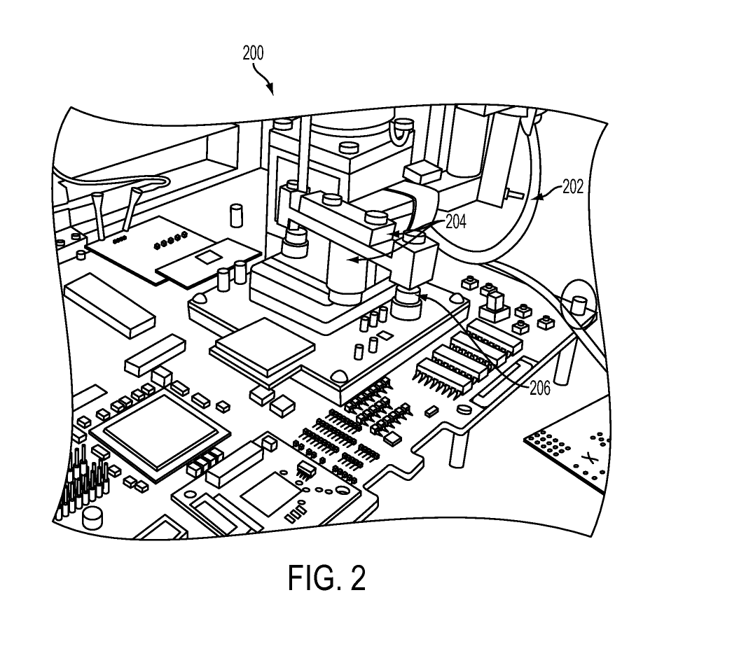

FIG. 2 depicts the test assembly 200 with handler swing arm. The handler swing arm optimizes the alignment and includes additional gross alignment features. A rubber gasket prevents over-rotation of the handler swing arm. A conformable air hose 202 is used to prevent sticking in the y-axis. FIG. 2 also shows added crossbar and circular metal collar 204, which helps keep the device level during testing. Secondary alignment features 206 are also depicted. These secondary alignment features 206 are used to locate the interface used in testing.

FIG. 3 illustrates the modified socket assembly that facilitates alignment of the swing arm and the compound nest. In particular, guide pins aid alignment and shoulder screws prevent drift of the aligned assembly. The modified socket assembly has locating holes or slots 302 that correspond to the locating holes or slots in the CDP socket to facilitate alignment. The swing arm is held in alignment by the guide pins in the CDP base plate and handler base plate. These guide pins better align the swing arm to the CDP socket and also prevent drift. The shoulder screws 304 provide fine tuning of hole and fastener alignment, which is especially important when fine pitch devices (0.4 mm and 0.5 mm) are being tested. In particular, shoulder screws 304 provide for finer alignment between the test head and the socket.

FIG. 4 is a flowchart of a method of using the high volume logic testing apparatus. The method 400 begins when a logic device is installed in a compound nest in step 402. The compound nest is then attached to the handler arm in step 404. In step 406 the compound nest is aligned with the socketed assembly using the guide pins and shoulder screws for optimum alignment. Once the compound nest is aligned the logic device is tested in step 408.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An apparatus for testing logic devices with an attached memory device, comprising:
a handler arm;
a compound nest attached to the handler arm;
a swing arm; and
a socketed assembly that facilitates alignment.

2. The apparatus of claim 1, wherein the compound nest encompasses a high speed memory chip.

3. The apparatus of claim 2, wherein the compound nest accommodates high speed memory chips of various thicknesses.

4. The apparatus of claim 1 further comprising a test head interface plate.

5. The apparatus of claim 3, further comprising a spring loaded platen.

6. The apparatus of claim 1, wherein the compound nest incorporates spring loading.

7. The apparatus of claim 1, wherein the compound nest includes locating pins.

8. The apparatus of claim 1, wherein the compound nest includes locking pins.

9. The apparatus of claim 1, wherein the swing arm includes a rubber gasket.

10. The apparatus of claim 1, wherein the swing arm includes a conformable air hose.

11. The apparatus of claim 1, wherein the swing arm includes a crossbar and circular metal collar.

12. The apparatus of claim 1, wherein the socketed assembly includes guide pins and shoulder screws.

13. The apparatus of claim 1, wherein the socketed assembly has locating holes or slots.

14. A method for testing logic devices having an attached memory, comprising:
installing a logic device in a compound nest;
attaching the compound nest to a handler arm;
aligning the compound nest with a socketed assembly; and
testing the logic device and attached memory.

15. The method of claim 14, wherein aligning the compound nest is performed by holding the swing arm using guide pins in a base plate of the socketed assembly and handler arm base plate.

16. The method of claim 15, wherein the alignment is further refined using shoulder screws.

17. An apparatus for testing logic devices having an attached memory, comprising:
means for installing a logic device in a compound nest;
means for attaching the compound nest to a handler arm;
means for aligning the compound nest with a socketed assembly; and
means for testing the logic device and attached memory

18. The apparatus of claim 17, further comprising means for further refining alignment of the compound nest with a socketed assembly.

19. The apparatus of claim 17, wherein a device installed in the logic device is a first chip having test pads on a top side and a second device installed into a compound nested socket.
